(19) United States
(12) Patent Application Publication
(10) Pub. No.: US 2025/0033956 A1
(43) Pub. Date: Jan. 30, 2025

(54) METHOD FOR PROCESSING SILICON SUBSTRATE AND METHOD FOR PROCESSING LIQUID EJECTION HEAD SUBSTRATE

(71) Applicant: CANON KABUSHIKI KAISHA, Tokyo (JP)

(72) Inventor: ATSUNORI TERASAKI, Kanagawa (JP)

(21) Appl. No.: 18/775,279

(22) Filed: Jul. 17, 2024

(30) Foreign Application Priority Data
Jul. 26, 2023 (JP) 2023-121595

(51) Int. Cl. B81C 1/00; B41J 2/14; B41J 2/16; B81B 1/00

(52) U.S. Cl. CPC B81C 1/00087; B41J 2/14016; B41J 2/1601; B41J 2/1626; B41J 2/164; B81B 1/004; B81B 2201/052; B81C 2201/0132; B81C 2201/053

(57) ABSTRACT

A method for processing a silicon substrate is provided the method including repeatedly and alternately performing: an etching step of forming an etching pattern on the silicon substrate; and a protective film formation step of forming a protective film on a wall surface of the silicon substrate exposed in the etching step, wherein the method includes a protective film removal step of removing the protective film, which has been formed in the protective film formation step, by using a peeling solution, and wherein in the protective film formation step, the protective film is formed by using a mixed gas including 2,3,3,3-tetrafluoropropene and perfluorocyclobutane.

### BACKGROUND OF THE INVENTION

### Field of the Invention

The present invention relates to a method for processing a silicon substrate, and mainly relates to a method for processing a silicon substrate to be used in a liquid ejection head.

### Description of the Related Art

In general Micro Electro Mechanical Systems (MEMS) processing and some semiconductor device processing, there are many examples of processing structures that penetrate a silicon substrate or have a depth corresponding to the thickness thereof. Currently, silicon substrates used in liquid ejection heads are processed by applying semiconductor device microfabrication technology. In a typical liquid ejection head used in a liquid ejection printing method, a flow path forming member is formed in a silicon substrate.

The flow path forming member is configured of an ejection port for ejecting droplets, and a liquid flow path connected to the ejection port. Generally, a plurality of liquid flow paths is arranged in a row. Further, an ejection energy generating element is provided on the silicon substrate in a part of the liquid flow path, and droplets are ejected from the ejection ports by the energy generated by the ejection energy generating element. Furthermore, a plurality of liquid supply ports connected to respective liquid flow paths, and a common liquid chamber communicating with these liquid supply ports are formed in the silicon substrate.

In such a configuration, droplets are ejected from the ejection port by heating and foaming the liquid by using, for example, thermal energy from an ejection energy generating element such as an ejection heater. At that time, the liquid is supplied from the supply port to the liquid flow path, and the liquid is supplied from the common liquid chamber to the supply port.

When forming such a supply port, an opening in the silicon substrate is required, and vertical processing using dry etching may be used from the viewpoint of improving density. Plasma etching in which an etching step and a deposition film formation step are alternately repeated is preferably used for etching silicon substrates. Specifically, the technique includes cycles in which the following three steps are continuously repeated in this order.
(1) Silicon etching step using fluorine-based radicals.
(2) Fluorocarbon-based deposition film formation step.
(3) Removal step of the deposition film at the pattern bottom portion by using ions.

By continuing to protect the sidewalls of the etching pattern formed in step (1) with the deposition film (hereinafter referred to as deposit film) formed in step (2), a vertical etched shape can be achieved. This enables high-speed processing of silicon. As the processing gas, perfluorocyclobutane (C₄F₈) is usually used in step (2), and sulfur hexafluoride (SF₆) is usually used in the steps (1) and (3). The gas used in step (2) is hereinafter referred to as deposit gas.

In the above step (2), 2,3,3,3-tetrafluoropropene may be used as the deposit gas, as shown in Japanese Patent Application Publication No. 2014-138122. The rational formula of this gas is C₃H₂F₄ and is sometimes abbreviated as HFO. It is known that that deposit film formed with HFO functions as a protective film with a thickness smaller than that of C₄F₈. Therefore, the deposit film formation time is short, and the etching time for removing the bottom portion deposit film is short. This is synonymous with improving the etching rate, and the resultant advantage is that the process time is shortened. Furthermore, the global warming potential of fluorocarbon-based gases, which is a problem, is 10,300 for C₄F₈, while being extremely low at 4 for HFO, thereby making it an attractive option.

The characteristic feature of the fluorocarbon-based deposit films formed in the above etching method is that the films are formed in locations in the substrate that are unlikely to be bombarded by ions supplied from plasma, primarily the sidewalls of the etched pattern. If left as they are, the films may detach from the substrate and become foreign matter in the subsequent production steps. Therefore, the films have to be removed. Examples of the removal method include ashing using oxygen plasma or cleaning using a chemical solution.

Ashing using oxygen plasma is highly reliable for removing fluorocarbon-based deposit films. However, when an organic film is present as a structure on the surface, or when it is highly desirable to prevent the surface from oxidation, the use of such ashing may be limited. In such cases, cleaning with a chemical solution is effective in removing the deposit film. Chemical solutions used for cleaning deposit films are of a swelling-and-peeling type, a dissolving type, and a combined swelling-and-peeling and dissolving type. Hydrofluoroethers (HFE) are an example of chemical solutions of a swelling-and-peeling type. Such chemical solutions have very high permeability and can penetrate into the deposit film, thereby causing the film to swell and be peeled off from the substrate. However, hydrofluoroether (HFE) chemical solutions do not have the ability to dissolve deposited films. Therefore, there is a concern that the deposit film may float in the liquid and re-adhere to the substrate, generating foreign matter.

Meanwhile, examples of chemical solutions of a dissolving type or a combined swelling-and-peeling and dissolving type include peeling solutions containing hydroxylamine. Since hydroxylamine has a high ability to dissolve metal oxide residues (dry etching residues) by a reducing action, a peeling solution containing such a component is suitably used in an insulating film etching step of semiconductors. In semiconductor processes, it is common to remove resist and fluorocarbon-based deposit films by ashing, and then remove metal oxide residues, but it has been found that such peeling solutions can also dissolve fluorocarbon-based deposit films. Although the details of the reaction are not clear, it is thought that the peeling solution penetrates into the deposit film to swell and peel off the film and then dissolves the film itself, and such solutions have been also used for removing deposit films. More broadly, it is known that a peeling solution containing an amine and an organic polar solvent has the ability to dissolve deposit films.

### SUMMARY OF THE INVENTION

However, it has been revealed that the deposit film formed with the conventional C₄F₈ deposit gas dissolves in the peeling solution as described above, whereas the deposit film formed with the HFO deposit gas hardly dissolves. As a result, the deposit film formed of HFO could not be dissolved and removed by the peeling solution.

In order to solve the above-mentioned problems, an object of the present invention is to provide a method for forming a deposit film that dissolves in a peeling solution in silicon etching using a deposit film containing HFO.

In order to achieve the above object, in the method for processing a silicon substrate in the present invention, the following steps are alternately repeated:
an etching step of forming an etching pattern on the silicon substrate; and
a protective film formation step of forming a protective film on a wall surface of the silicon substrate exposed in the etching step, wherein the method for processing a silicon substrate includes a protective film removal step of removing the protective film, which has been formed in the protective film formation step, by using a peeling solution, and
wherein in the protective film formation step, the protective film is formed by using a mixed gas including 2,3,3,3-tetrafluoropropene and perfluorocyclobutane.

In addition, in order to achieve the above object, the method for processing a liquid ejection head substrate in the present invention,
an etching step of forming an etching pattern on the liquid ejection head substrate; and
a protective film formation step of forming a protective film on side walls of the liquid ejection head substrate exposed in the etching step,
with at least one of a liquid supply port for supplying liquid and a flow path communicating with the liquid supply port being formed in the liquid ejection head substrate,
wherein the method for processing a liquid ejection head substrate includes a protective film removal step of removing the protective film, which has been formed in the protective film formation step, by using a peeling solution, and
wherein in the protective film formation step, the protective film is formed by using a mixed gas including 2,3,3,3-tetrafluoropropene and perfluorocyclobutane.

According to the present invention, a deposit film containing HFO can be dissolved in a peeling solution.

Further features of the present invention will become apparent from the following description of exemplary embodiments with reference to the attached drawings.

### BRIEF DESCRIPTION OF THE DRAWINGS

FIG. 1 is a conceptual diagram of the process in which a deposit film is formed with C₄F₈;

FIGS. 2A to 2D are explanatory diagrams showing how the formed deposit film is dissolved in a peeling solution;

FIG. 3 is a diagram showing the time required for the deposit film to dissolve in the peeling solution;

FIGS. 4A and 4B are explanatory diagrams of passivation breakdown in which silicon is eroded;

FIG. 5 is a diagram showing the decrease, in the depth direction, of the components forming the deposit film;

FIGS. 6A to 6D are explanatory diagrams of a method for manufacturing a liquid ejection head in Example 3; and

FIGS. 7A to 7D are explanatory diagrams of a method for manufacturing a liquid ejection head in Example 3.

### DESCRIPTION OF THE EMBODIMENTS

A mode for carrying out the present invention will be illustratively described hereinbelow in detail based on examples with reference to the drawings. The dimensions, materials, shapes, and relative arrangement of the components described in the embodiments should be changed as appropriate depending on the configuration of the device to which the invention is applied and various conditions. Furthermore, not all combinations of features described in the present embodiment are essential to the solution of problems according to the present invention. The constituent elements described in the embodiments are merely exemplary, and the scope of the present invention is not intended to be limited thereto.

Here, it is known that the deposit film formed with 2,3,3,3-tetrafluoropropene (hereinafter referred to as HFO) functions as a protective film with a thickness smaller than that of perfluorocyclobutane (hereinafter referred to as C₄F₈). This means that the resistance to etching by SF₆ is high, but at the same time, there is a possibility that the resistance to dissolution by a peeling solution is also high.

As for the reasons why the deposit film formed with HFO has higher etching resistance than that formed with C₄F₈, Japanese Patent Application Publication No. 2014-138122 infers that:
the C/F ratio is higher in the deposit film formed with HFO than in the deposit film formed with C₄F₈;
the number of carbon-carbon bonds (C—C bonds) is large; and
a three-dimensional carbon-carbon network is constructed.

The difference in the average molecular length of the deposit film is considered as another possible reason. It is known that the solubility of deposit films formed with C₄F₈ varies depending on plasma conditions. As a tendency, films formed under conditions of higher plasma density are more likely to dissolve.

The process of forming a deposit film with C₄F₈ includes the following steps:
(1) CₓF_{y} is formed by dissociation of a parent gas (the molecules become smaller);
(2) CₓF_{y} polymerizes to form long-chain molecules —(CF₂)ₙ—; and
(3) the long-chain molecules adhere to the substrate and further polymerize on the substrate.

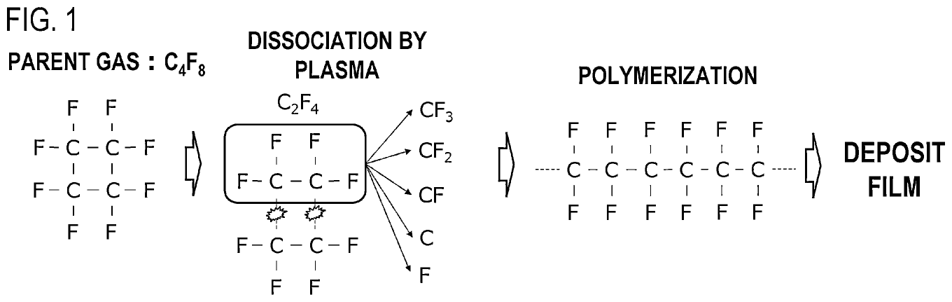

FIG. 1 shows the conceptual diagram of the process. It is considered that when the plasma density is high, the dissociation of (1) becomes active, and the molecular length of (2) during the polymerization process becomes relatively short, so it is possible that the dissolution is facilitated.

Although the difference between the deposit film formed with HFO and the deposit film formed with C₄F₈ cannot be discussed from the viewpoint of plasma density, it is consistent with the fact that where the molecular length of the deposit film formed with HFO is for some reason significantly greater than that formed with C₄F₈, the film is not dissolved in the peeling solution.

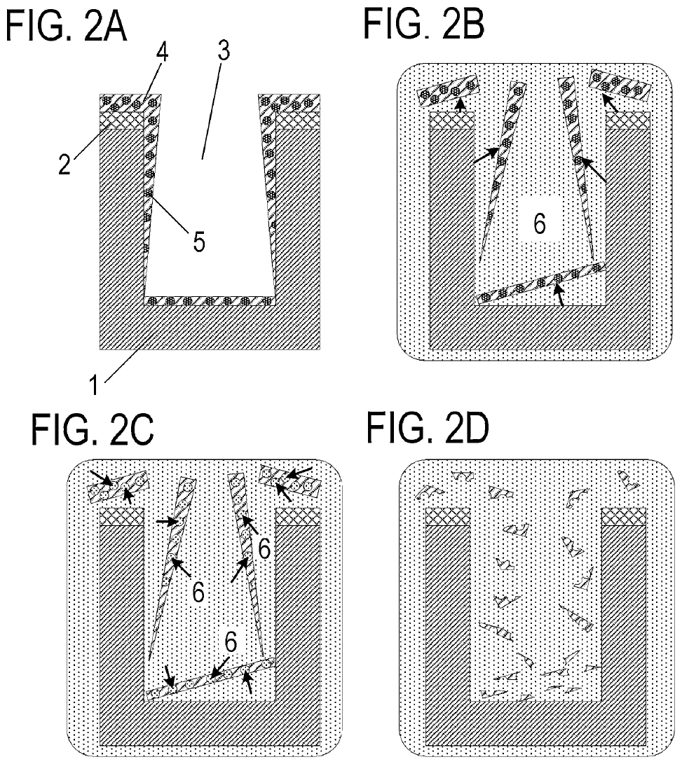

This time, the inventors have discovered that where a mixed gas is formed by adding C₄F₈ to HFO and a deposit film is formed with this mixed gas, the deposit film is soluble in the peeling solution. It is presumed that this is because a component derived from C₄F₈ is mixed into the HFO deposit film, which is difficult to dissolve in the peeling solution, thereby creating starting points for reaction with the peeling solution. Hereinafter, the steps from forming an etching pattern to forming a deposit film functioning as a protective film and further to removing the deposit film by using a peeling solution will be described using FIGS. 2A to 2D. As shown in FIG. 2A, in a step of forming an etching pattern (etching step), the surface of a substrate 1 is masked with a mask 2, and an etching pattern (pattern 3) is formed by etching (etching step). Then, in a step of forming a protective film (protective film formation step), a deposit film 4 made with the above-mentioned mixed gas obtained by mixing C₄F₈ with HFO is formed on the surface of the mask 2 and on the side wall (wall surface) inside the substrate exposed by etching (deposit film formation step). It is assumed that the component 5 derived from C₄F₈ is dispersed in the deposit film 4 formed with the mixed gas. Then, in a step of removing the deposit film 4 functioning as a protective film (protective film removal step), the deposit film 4 including the component 5 derived from C₄F₈ is swelled, peeled off, and removed from the wall surface (deposit film removal step) by immersion into the peeling solution 6, as shown in FIG. 2B, and then the peeling solution 6 is introduced into the component 5 derived from C₄F₈, as shown in FIG. 2C. Finally, in the final assumed image, the entire deposit film is split from the inside and dissolved in the peeling solution 6, as shown in FIG. 2D. This is considered to hold true even when any of the mechanisms described above is assumed.

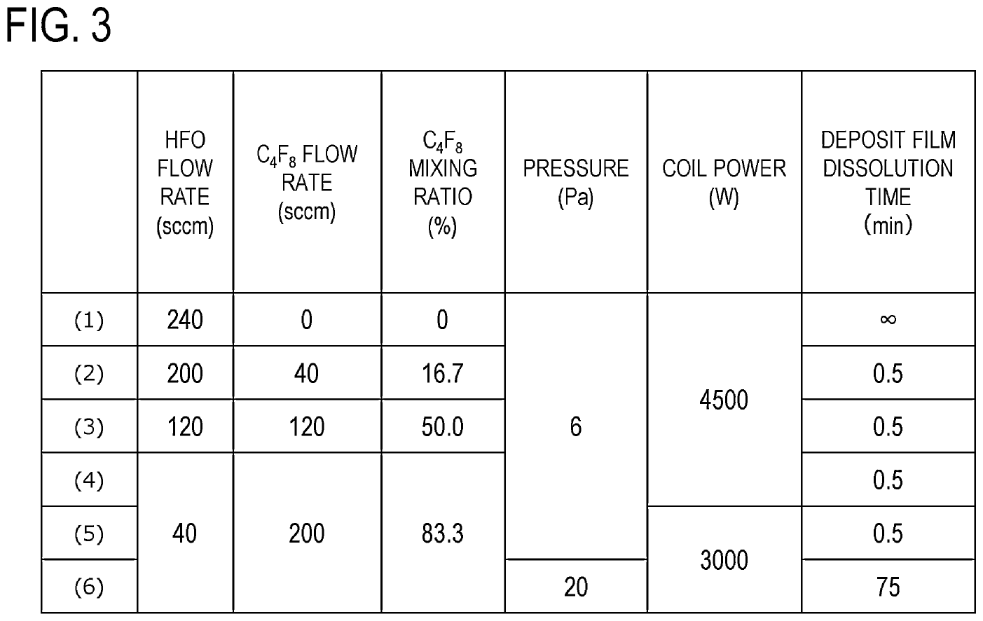

FIG. 3 shows the time that was required for the deposit film to dissolve in the peeling solution when the mixing ratio of C₄F₈ in the mixed gas was varied by varying the flow rate of HFO and the flow rate of C₄F₈. The deposit film used was formed to a thickness of 200 nm to 300 nm only in the step of forming the deposit film as a protective film (deposit film formation step). The peeling solution contains an amine and an organic polar solvent. Incidentally, the resist or deposit film is dissolved as the peeling solution penetrates therein and causes decomposition, so the dissolution time is not simply proportional to the film thickness. Therefore, since it is difficult to specify the dissolution rate (nm/min etc.), the dissolution rate is expressed herein in terms of dissolution time. In the present verification, the solubility improved at least at a C₄F₈ mixing ratio of 16.7% or higher, and at higher mixing ratios, saturation was substantially reached and the dissolution time remained constant. With this assumed mechanism, it is expected that the effect will be exhibited even at a low mixing ratio, and it is assumed that dissolution will be achieved even at a mixing ratio of about 5%.

The upper limit of the mixing ratio is not particularly restricted. However, as the mixing ratio of C₄F₈ increases, it becomes easier to dissolve in the peeling solution, but the etching resistance decreases. It is necessary to select an appropriate value in consideration of productivity, and actually where the mixing ratio exceeds 80%, the advantage of using HFO for the deposit film is almost lost. Therefore, the mixing ratio of C₄F₈ in the deposit film containing HFO needs to be higher than 16.7% and not more than 80%.

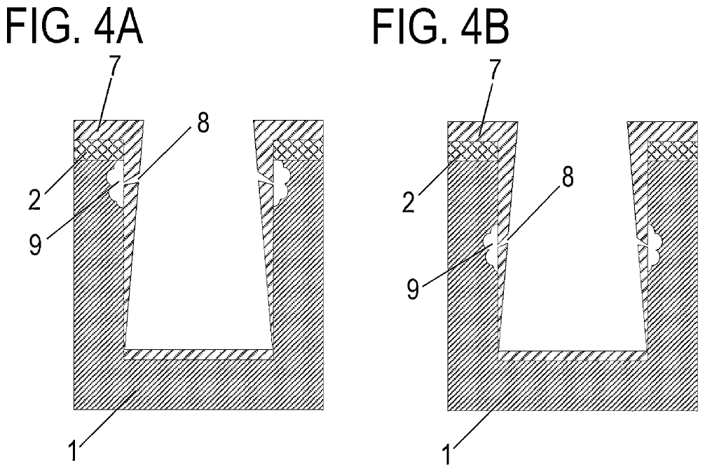

Meanwhile, etching using a deposit film containing HFO has another aspect. In vertical etching of silicon substrates, there is a phenomenon called passivation breakdown, in which silicon is eroded when the etched wall surface is not sufficiently protected, and usually such phenomenon often occurs near openings that are exposed to etching gas including SF₆ for a long time during etching pattern formation, as shown in FIG. 4A. The etching gas enters the deposit film 7 (a general protective film; HFO or C₄F₈ is not particularly specified) shown in the figure through a path 8, causing passivation breakdown 9. However, in etching using a deposit film containing HFO, in a pattern with a high aspect ratio (etching depth/etching opening width), the sidewall may be torn in the middle of the wall in the depth direction, which causes passivation breakdown 9, as shown in FIG. 4B.

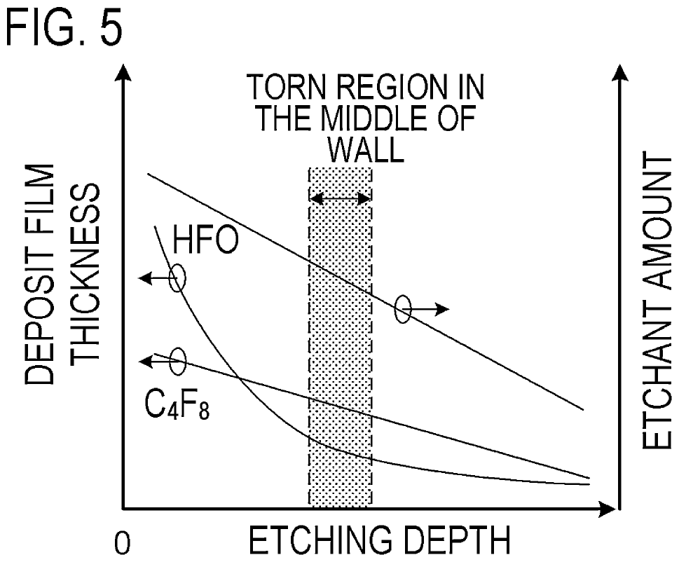

Generally, in etching patterns with high aspect ratios, a phenomenon called microloading occurs, and it becomes difficult for ions and radicals, which are the source of etching and deposition, to penetrate deep into the pattern. The occurrence of the passivation breakdown 9 in the middle of the sidewall suggests that the decrease in the amount of components forming the CF-based deposit film in the depth direction proceeds faster than the decrease in the amount of F radicals, which are the etchant necessary for etching, in the depth direction, and the balance is lost which results in the appearance, along the way, of places that cannot be protected. That is, it is possible to arrive at the result shown in FIG. 4B by assuming that where the amount of etchant decreases, for example, linearly with depth, the thickness of the deposit film formed with C₄F₈ decreases linearly in almost the same manner, whereas the HFO deposit film adheres in a large amount close to the opening and the thickness thereof slowly decreases therefrom with depth, as shown in FIG. 5. That is, it is inferred that the deposit film formed with HFO has a high probability of adhering to the surface and is difficult to penetrate deep. For example, such a phenomenon may occur when it is assumed that HFO has a larger average molecular length than the deposit film formed with C₄F₈ as described above.

In such a case, it is necessary to make changes such as increasing the thickness of the deposit film or reducing the etching time in order to improve the protection of the sidewall by the deposit film. As a result, the effect of shortening the process time, which is the advantage of HFO, may be reduced.

To solve this problem, in the present embodiment, a manufacturing method can be adopted in which the above-described process of mixing C₄F₈ with HFO is applied and the mixing ratio of C₄F₈ is gradually increased. Since it is assumed that C₄F₈ has a higher deposition film coverage rate at high aspect ratios, as shown in FIG. 5, by increasing the mixing ratio of C₄F₈, it is possible to complement the protective property at a high aspect ratio, which is the weak point of HFO, by the components derived from C₄F₈.

In the above-mentioned mixing ratio gradient process, the mixing ratio of C₄F₈ may be increased to change continuously, or the mixing ratio of C₄F₈ may be fixed at a constant value in the initial stage of deposit film formation, and then the mixing ratio of C₄F₈ may be increased stepwise in several stages. The initial C₄F₈ mixing ratio may be 0%. This is because the initial deposit film is attached near the opening, so it can be easily removed by the peeling solution, and it may be acceptable even if the deposit film is not completely dissolved. The essential condition of this case is that at least a part of the deposit film formed during the process is a film that dissolves in the peeling solution. Moreover, conversely, the deposit gas of the final stage may be 100% only C₄F₈. In other words, where the dissolution time when a mixed gas with a C₄F₈ mixing ratio of 16.7% to 80% is used for deposit film formation is shorter than the dissolution time when only HFO is used for deposit film formation, this corresponds to the configuration of the invention that solves the problem of the present invention, and even if the mixing ratio therebefore and thereafter falls outside of that range, the process as a whole satisfies the requirements for solving the problem of the present invention.

In this way, by using a mixed gas in which C₄F₈ is mixed with a deposit gas using HFO to form a deposit film, it is possible to enhance the solubility of the deposit film without significantly degrading the effects of shortening the process time and reducing the global warming coefficient, which are the advantages of silicon etching using HFO.

### Example 1

As Example 1 of the present invention, a pattern having a width of 200 μm, a length of 20,000 μm, a depth of 500 μm, and an aspect ratio of 2.5 was etched on a silicon substrate (hereinafter simply referred to as the substrate). As mentioned in the Background Art section, the process of etching in this example is a cycle in which the following three steps are continuously repeated in this order.
(1) Silicon etching step using fluorine-based radicals (etching step).
(2) Fluorocarbon-based deposition film formation step (protective film formation step).
(3) Removal step of the deposition film at the bottom portion of the pattern using ions.

These steps may start from (1) or may start from (2). (2) is called a deposition film formation step, and (3)→(1) is called an etching step.

A mask with the pattern that is wished to be etched is formed on the substrate, and the recess thereof is etched (1). A deposition film (hereinafter referred to as deposit film) is formed on the exposed new silicon surface (2). Next, the deposit film at the bottom portion of the pattern is selectively removed using ions. As a result, silicon is exposed at the bottom portion of the pattern, so that etching proceeds according to the next step (1). From the second cycle onward, the deposit film is deposited not only on the newly exposed surface but also on the already exposed surface.

The deposit film was formed on the exposed wall surface of the substrate by forming an etching pattern under an HFO flow rate of 200 sccm, a C₄F₈ flow rate of 40 sccm, and a C₄F₈ mixing ratio of 16.7% as the conditions of the deposit film formation step. It was possible to realize an etching shape with no significant difference as compared to that when the deposit film was formed under an HFO flow rate of 240 sccm, a C₄F₈ flow rate of 0 sccm, and a C₄F₈ mixing ratio of 0% as the conditions of the deposit film formation step.

The etching rate when only C₄F₈ was used as the deposit gas was 7.8 μm/min, whereas an etching rate of 9.5 μm/min could be obtained under the above conditions of an HFO flow rate of 200 sccm, a C₄F₈ flow rate of 40 sccm, and a C₄F₈ mixing ratio of 16.7%. The productivity could be improved by approximately 1.3 times.

It was confirmed that the deposit film formed in the above-mentioned deposit film formation step was dissolved in the peeling solution containing an amine and an organic polar solvent in the above-mentioned protective film removal step. The processing conditions were 60° C. for 30 min. This made it possible to both improve productivity and dissolve the deposit film in the peeling solution.

### Example 2

As Example 2 of the present invention, a pattern with a width of 20 μm, a length of 40 μm, a depth of 250 μm, and an aspect ratio of 12.5 was etched on a silicon substrate. This corresponds to a high aspect ratio pattern. The etching step in this example is the same as in Example 1, and the description thereof will therefore be omitted.

Under the condition of using only C₄F₈ as the deposit gas, the etching rate was 12.3 μm/min, whereas when HFO was also used as the deposit gas and the HFO flow rate was 240 sccm, the etching rate was 17.6 μm/min. However, under the same conditions, sidewall rupture and passivation breakdown occurred at a depth of around 100 μm.

When conditions were optimized by increasing the time for the deposit film formation step and decreasing the time for the etching step in order to resolve these problems, the etching rate was 11.7 μm/min, which was lower than when only C₄F₈ was used as the deposit gas.

Here, the total flow rate of HFO and C₄F₈ was fixed at 240 sccm, and at the initial stage of deposit film formation, the C₄F₈ flow rate was 40 sccm and the C₄F₈ mixing ratio in the deposit gas was 16.7%. From there, the C₄F₈ mixing ratio was gradually increased continuously, and finally the C₄F₈ flow rate was 120 sccm and the C₄F₈ mixing ratio was 50.0%. This made it possible to suppress passivation breakdown near a depth of 100 μm. However, since the amount of deposit film at the bottom increased as a result of increasing the mixing ratio of C₄F₈ in the deposited gas, it took time to remove the deposit film at the bottom, and the etching rate decreased accordingly. As a result, the etching rate was 13.5 μm/min, which was better than when only C₄F₈ was used as the deposit gas. It is conceivable that through further optimization, it would be possible to improve the rate a little more without causing passivation breakdown.

Furthermore, it was confirmed that the deposit film formed in the above-described deposit film formation step was dissolved in the peeling solution containing an amine and an organic polar solvent in the above-mentioned protective film removal step. The treatment conditions were 60° C. for 30 min. This made it possible to both improve productivity and dissolve the deposit film in the peeling solution.

### Example 3

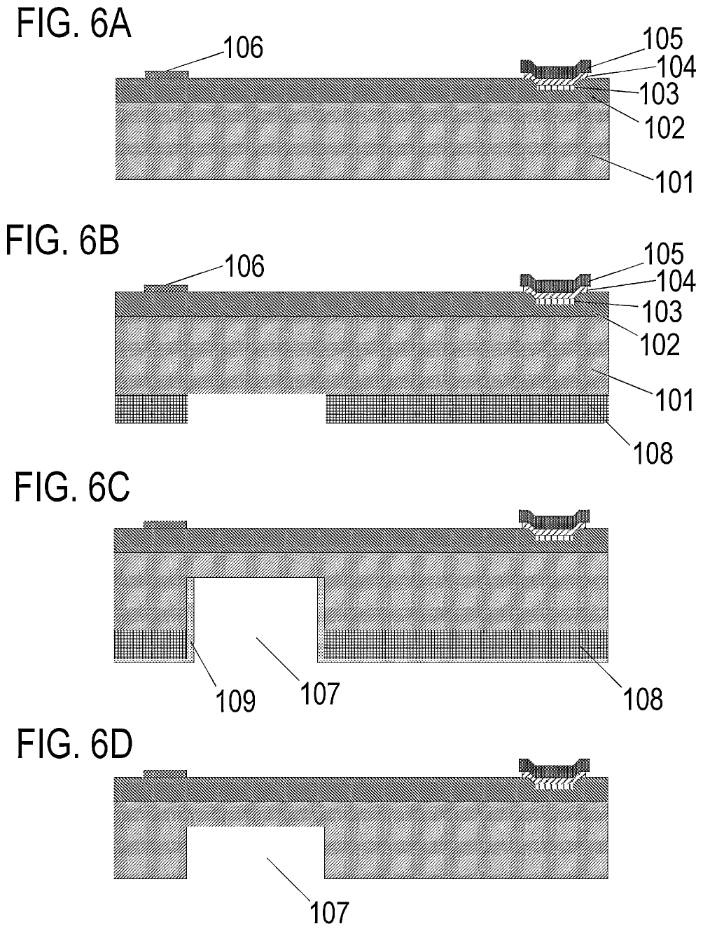

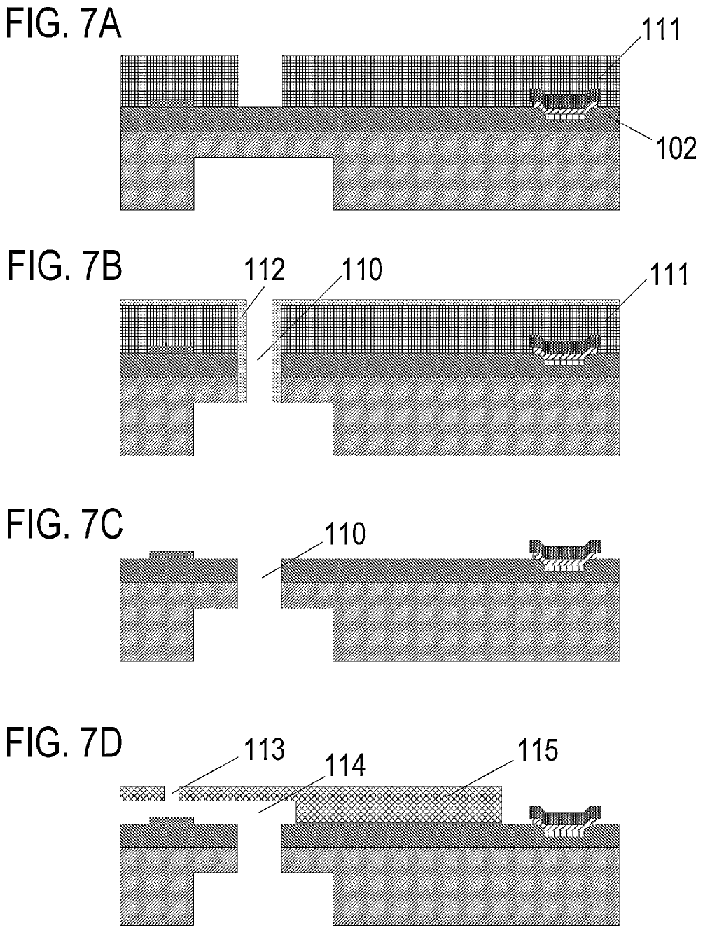

As Example 3 of the present invention, a method for manufacturing a liquid ejection head having a structure as shown in FIGS. 6A to 6D and FIGS. 7A to 7D will be described. As for the residue of the deposit film, since the remaining deposit film may turn into foreign matter and cause ejection abnormalities, it is necessary to dissolve and remove the deposit film in a pattern in which silicon is processed by plasma etching. A wiring formation layer 102 having an ejection energy generating element 106 and including the ejection energy generating element 106 and wiring 103 was formed on a silicon substrate 101 for a liquid ejection head (hereinafter simply referred to as substrate 101). The wiring 103 was made of Al doped with Cu, and in order to take out an electrode from this Al wiring, TiW was formed as an adhesion layer 104 and Au was formed as an electrode 105 (FIG. 6A).

Dry etching of silicon or a silicon-based insulating film was performed on the substrate 101 in order to finally form a liquid supply port 110 that supplied liquid to an ejection port 113 of the liquid ejection head. In the present example, first, on the surface opposite to the surface having the wiring formation layer 102, using a novolak-based positive resist 108 as a mask, masking was performed on a region other than the surface where a common flow path 107 is to be formed, and dry etching was performed to form a recess (etching pattern) necessary for forming the common flow path 107 communicating with the liquid supply port 110 (FIG. 6B). Then, by using the deposit gas under the conditions for low aspect ratio used in Example 1 of silicon etching of the present invention, that is, under an HFO flow rate of 200 sccm, a C₄F₈ flow rate of 40 sccm, and a C₄F₈ mixing ratio of 16.7%, a fluorocarbon-based deposit film 109 was formed on the surface of the resist 108 and the recess of the substrate 101 where the common flow path 107 is to be formed. Next, the deposit film 109 formed on the bottom of the recess was selectively removed. After that, dry etching was performed again on the bottom surface of the recess from which the deposit film had been removed. Then, since the side walls inside the substrate 101 on which the deposit film 109 was not formed were exposed, the deposit film 109 was formed again on the surface of the resist 108 and the above-mentioned recess, including the side walls inside the substrate 101 that had already been etched. Then, the deposit film 109 formed on the bottom surface of the recess was selectively removed again and dry etching was performed. By repeating this series of steps and performing vertical processing by dry etching, the common flow path 107 was formed (FIG. 6C). This common flow path 107 had an opening width of approximately 200 μm, a depth of approximately 450 μm, and an aspect ratio of 2.25.

Subsequently, a part of the resist surface altered by dry etching was removed by ashing, and then the remaining resist 108, which was masking the surface of the substrate 101, and the deposit film 109 covering the side walls inside the substrate were removed with a peeling solution (FIG. 6D). When peeling off the deposit film 109, a peeling solution containing an amine and an organic polar solvent was used, and the treatment conditions were 60° C. for 30 min. It could be confirmed that the deposit film 109 was dissolved in the peeling solution without any problem.

Next, on the side having the wiring formation layer 102, using a novolak-based positive resist 111 as a mask, masking was performed on a region other than the portion where the liquid supply port 110 is to be formed, and dry etching was performed to form a recess (etching pattern) necessary for forming the liquid supply port 110 (FIG. 7A). Next, a silicon-based interlayer insulating film of the wiring formation layer 102 was opened by dry etching with a fluorocarbon-based etchant, and then by using the deposit gas under the conditions for high aspect ratio used in Example 2 of silicon etching of the present invention, that is, a total flow rate of HFO and C₄F₈, i.e., 240 sccm, and a flow rate of C₄F₈, i.e., 40 sccm, and a C₄F₈ mixing ratio of 16.7% at the initial stage of deposit film formation, a fluorocarbon-based deposit film 112 was formed on the surface of the resist 111 and the recess where the liquid supply port 110 is to be formed. Next, the deposit film 112 formed on the bottom surface of the recess was selectively removed. After that, dry etching was performed again on the bottom surface of the recess from which the deposit film had been removed. Then, since the side walls inside the substrate 101 on which the deposit film 112 was not formed were exposed, the deposit film 112 was formed again on the surface of the resist 111 and the above-mentioned recess, including the side walls inside the substrate 101 that had already been etched. The deposit film 112 formed on the bottom surface of the recess was selectively removed again and dry etching was performed. While repeating this series of steps, the C₄F₈ mixing ratio in forming the deposit film was gradually increased continuously, and finally the deposit film 112 was formed using a deposit gas with a C₄F₈ flow rate of 120 sccm and a C₄F₈ mixing ratio of 50.0%. Then, in the same way as when forming the common flow path 107, the liquid supply port 110 communicating with the common flow path 107 was formed by performing vertical processing using dry etching (FIG. 7B). This liquid supply port 110 had an opening width of approximately 20 μm, a depth of approximately 170 μm, and an aspect ratio of 8.5. When etching a pattern with such a high aspect ratio, with a deposit film using HFO gas, passivation breakdown is likely to occur on the sidewalls. Therefore, bubble accumulation and the like may occur in the grooved areas caused by etching. However, as mentioned above, the stepwise increase in the mixing ratio of C₄F₈ contained in the deposit gas that forms the deposit film is effective, and it is possible to suppress the occurrence of passivation breakdown and the occurrence of bubble accumulation and the like.

Subsequently, a part of the resist surface altered by dry etching was removed by ashing, and then the remaining resist 111, which was masking the surface of the wiring formation layer 102, and the deposit film 112 covering the side walls inside the substrate were removed with a peeling solution (FIG. 7C). The peeling solution containing an amine and an organic polar solvent was used, and the treatment conditions were 60° C. for 30 min. It could be confirmed that the deposit film 112 was dissolved in the peeling solution without any problem. The above-described steps constitute the method for processing the liquid ejection head substrate 101 in the present example.

The shape and time required for etching can be optimized by using appropriately the pattern of the mixing ratio of C₄F₈ contained in the deposit gas according to the aspect ratio of the pattern to be produced, for example, by maintaining the mixing ratio at a fixed value or creating a gradient by increasing the mixing ratio in a stepwise manner, as in the present example. Moreover, the deposit film could be dissolved in the peeling solution.

In the present example, the ejection port 113 for ejecting droplets and a liquid flow path 114 connected to the ejection port were then formed using an organic structure 115 (FIG. 7D). Through the above steps, a liquid ejection head could be manufactured.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-121595, filed on Jul. 26, 2023, which is hereby incorporated by reference herein in its entirety.

What is claimed is:

1. A method for processing a silicon substrate, the method comprising repeatedly and alternately performing:
an etching step of forming an etching pattern on the silicon substrate; and
a protective film formation step of forming a protective film on a wall surface of the silicon substrate exposed in the etching step,
wherein the method for processing a silicon substrate includes a protective film removal step of removing the protective film, which has been formed in the protective film formation step, by using a peeling solution, and
wherein in the protective film formation step, the protective film is formed by using a mixed gas including 2,3,3,3-tetrafluoropropene and perfluorocyclobutane.

2. The method for processing a silicon substrate according to claim 1,
wherein a mixing ratio of the perfluorocyclobutane in the mixed gas is at least 16.7% and not more than 80%.

3. The method for processing a silicon substrate according to claim 2,
wherein in the protective film formation step, the mixing ratio is constant.

4. The method for processing a silicon substrate according to claim 2,
wherein in the protective film formation step, the mixing ratio is gradually increased.

5. The method for processing a silicon substrate according to claim 1,
wherein in the protective film removal step, the protective film is removed by using a peeling solution including an amine and an organic polar solvent.

6. A method for processing a liquid ejection head substrate, the method comprising repeatedly and alternately performing:
an etching step of forming an etching pattern on the liquid ejection head substrate; and
a protective film formation step of forming a protective film on side walls of the liquid ejection head substrate exposed in the etching step,
with at least one of a liquid supply port for supplying liquid and a flow path communicating with the liquid supply port being formed in the liquid ejection head substrate,
wherein the method for processing a liquid ejection head substrate includes a protective film removal step of removing the protective film, which has been formed in the protective film formation step, by using a peeling solution, and
wherein in the protective film formation step, the protective film is formed by using a mixed gas including 2,3,3,3-tetrafluoropropene and perfluorocyclobutane.

7. The method for processing a liquid ejection head substrate according to claim 6,
wherein a mixing ratio of the perfluorocyclobutane in the mixed gas is at least 16.7% and not more than 80%.

8. The method for processing a liquid ejection head substrate according to claim 7,
wherein in the protective film formation step, the mixing ratio is constant.

9. The method for processing a liquid ejection head substrate according to claim 7,
wherein in the protective film formation step, the mixing ratio is gradually increased.

10. The method for processing a liquid ejection head substrate according to claim 6,
wherein in the protective film removal step, the protective film is removed by using a peeling solution including an amine and an organic polar solvent.
